(19) United States
(12) Patent Application Publication
(10) Pub. No.: US 2025/0030396 A1
(43) Pub. Date: Jan. 23, 2025

(54) Vibrator Device

(71) Applicant: SEIKO EPSON CORPORATION, Tokyo (JP)

(72) Inventors: Takayoshi KOGA, Minowa (JP); Yusuke YAMAMOTO, Minowa (JP); Ryuta NISHIZAWA, Nagano (JP); Atsushi MATSUO, Shiojiri (JP); Junichi TAKEUCHI, Chino (JP)

(21) Appl. No.: 18/777,985

(22) Filed: Jul. 19, 2024

(30) Foreign Application Priority Data
Jul. 21, 2023 (JP) 2023-118903

(51) Int. Cl. H03H 9/02; H03H 9/05; H03H 9/10; H03H 9/19

(52) U.S. Cl. CPC H03H 9/02125; H03H 9/0557; H03H 9/1021; H03H 9/19

(57) ABSTRACT

A vibrator device includes a vibrator element, a base to which the vibrator element is coupled, and a lid bonded to the base. The vibrator element is accommodated in an accommodation space between the lid and the base. At least one of the base or the lid includes a first semiconductor substrate connected to a ground potential and having a conductivity type that is p-type or n-type. The vibrator element includes a vibrator substrate, a first electrode disposed on a side of the vibrator substrate closer to the first semiconductor substrate, and a second electrode disposed on a side of the vibrator substrate farther from the first semiconductor substrate. L1≤0.2×10⁻³ and d1≥ε×S1×10¹², wherein L1 [m] is the height of the accommodation space, d1 [m] is the distance between the first semiconductor substrate and the first electrode, S1 [m²] is the area of the first electrode, and ε [F/m] is the permittivity of the accommodation space.

The present application is based on, and claims priority from JP Application Serial Number 2023-118903, filed Jul. 21, 2023, the disclosure of which is hereby incorporated by reference herein in its entirety.

### BACKGROUND

### 1. Technical Field

The present disclosure relates to a vibrator device.

### 2. Related Art

A vibrator device disclosed in JP-A-2020-28095 includes a base and a lid bonded together and a vibrator element accommodated in a space enclosed by the base and the lid. The base includes a p-type semiconductor or an n-type semiconductor. The lid is constituted of a semiconductor whose conductivity type is the same as the conductivity type of the semiconductor in the base. The semiconductor in the base and the semiconductor in the lid are connected to the ground potential.

However, when the vibrator device disclosed in JP-A-2020-28095 is used to form an oscillator, the parasitic capacitance between the base or the lid at the ground potential and an electrode of the vibrator element facing the base or the lid is increased. This results in the problem of deterioration of electrical characteristics, such as the start-up characteristics of the oscillator and the output characteristics of oscillation signals. Specifically, the deterioration of the electrical characteristics also includes a narrower variable frequency range and unstable oscillation start-up due to insufficient negative resistance of the oscillation circuit.

### SUMMARY

According to an aspect of the present disclosure, a vibrator device includes a vibrator element, a base, and a lid. The vibrator element is coupled to the base. The lid is bonded to the base, and the vibrator element is accommodated in an accommodation space between the lid and the base. At least one of the base or the lid includes a first semiconductor substrate connected to a ground potential and having a conductivity type that is p-type or n-type. The vibrator element includes a vibrator substrate, a first electrode, and a second electrode. The first electrode is disposed on a side of the vibrator substrate closer to the first semiconductor substrate. The second electrode is disposed on a side of the vibrator substrate farther from the first semiconductor substrate. L1 [m]≤0.2×10⁻³ and d1≥ε×S1×10¹², wherein L1 is the height of the accommodation space, d1 [m] is the distance between the first semiconductor substrate and the first electrode, S1 [m²] is the area of the first electrode, and ε [F/m] is the permittivity of the accommodation space.

### BRIEF DESCRIPTION OF THE DRAWINGS

FIG. 1 is a perspective view illustrating the schematic structure of a vibrator device according to a first embodiment.

FIG. 2 is a plan view illustrating the schematic structure of the vibrator device according to the first embodiment.

FIG. 3 is a sectional view taken along line III-III in FIG. 2.

FIG. 4 illustrates the relation between a distance d1 and a capacitance C between a first semiconductor substrate and a first electrode.

FIG. 5 is a plan view illustrating the schematic structure of a vibrator device according to a second embodiment.

FIG. 6 is a sectional view taken along line VI-VI in FIG. 5.

FIG. 7 is a plan view illustrating the schematic structure of a vibrator device according to a third embodiment.

FIG. 8 is a sectional view taken along line VIII-VIII in FIG. 7.

### DESCRIPTION OF EMBODIMENTS

### 1. First Embodiment

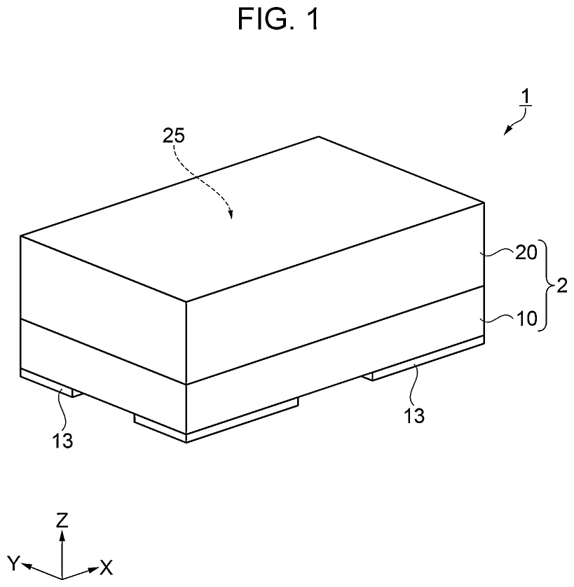

First, as a vibrator device 1 according to a first embodiment, an oscillator including a vibrator element 25 is described below by way of example with reference to FIGS. 1 to 4.

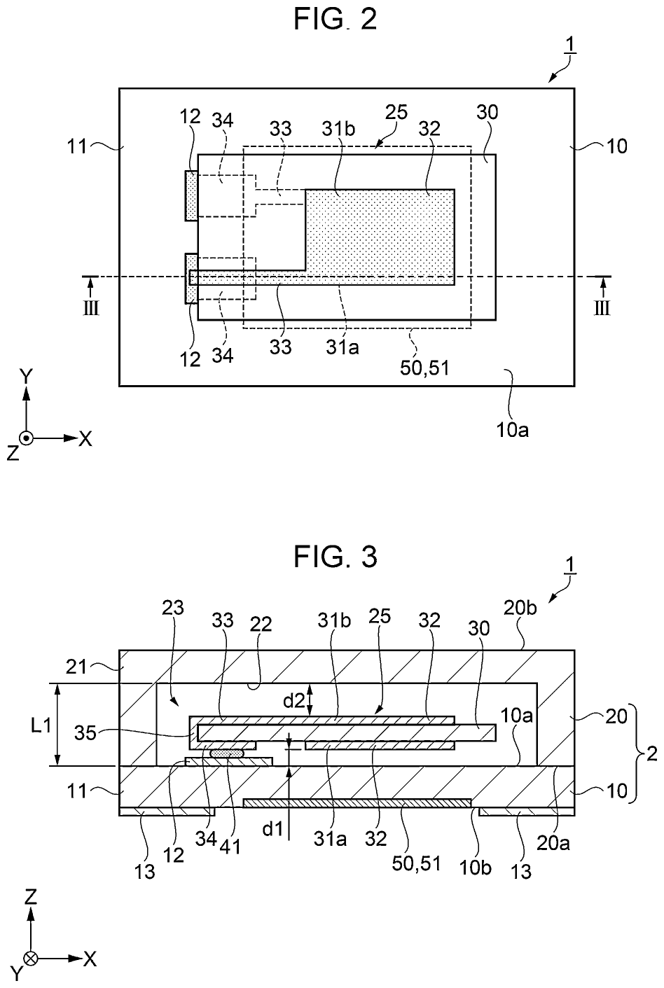

For convenience of describing the internal configuration of the vibrator device 1, FIG. 2 illustrates a state in which a lid 20 is removed from the vibrator device 1. For convenience of illustration, three axes orthogonal to one another, namely, an X axis, a Y axis, and a Z axis, are indicated in the perspective view, plan views, and sectional views below. The direction of the X axis, the direction of the Y axis, and the direction of the Z axis are hereinafter referred to as “X direction”, “Y direction”, and “Z direction”, respectively. The side of each axis indicated by the arrow is hereinafter also referred to “plus side”, and the opposite side is also referred to as “minus side”. The plus side in the Z direction and the minus side in the Z direction are also referred to as “upper” and “lower”, respectively.

As illustrated in FIGS. 1, 2, and 3, the vibrator device 1 includes the vibrator element 25, a base 10, and the lid 20. The vibrator element 25 is coupled to the base 10. The lid 20 is bonded to the base 10, and the vibrator element 25 is accommodated in an accommodation space 23 between the lid 20 and the base 10. The base 10 and the lid 20 constitute a package 2 in which the vibrator element 25 is accommodated.

The base 10 includes a first semiconductor substrate 11 and a circuit portion 50. The first semiconductor substrate 11 is connected to the ground potential and has a conductivity type that is p-type or n-type. The circuit portion 50 is located on a side of the first semiconductor substrate 11 farther from the vibrator substrate 25. The base 10 is a flat plate that is rectangular in shape when viewed in plan view in the Z direction. The base 10 has a first surface 10a and a second surface 10b on opposite sides. Internal terminals 12 are disposed on the first surface 10a, and external terminals 13 are disposed on the second surface 10b. The base 10 includes through-electrodes (not illustrated) extending between the first surface 10a and the second surface 10b and electrically connecting the internal terminals 12 to the circuit portion 50. The circuit portion 50 includes an oscillation circuit 51 which is electrically connected to the vibrator element 25.

The lid 20 includes a second semiconductor substrate 21 connected to the ground potential. The conductivity type of the second semiconductor substrate 21 is the same as the conductivity type of the first semiconductor substrate 11. The lid 20 is rectangular in shape when viewed in plan view in the Z direction. The lid 20 has a third surface 20a and a fourth surface 20b on opposite sides. The lid 20 has a recess 22 that is open on the base 10 side. The third surface 20a of the lid 20 is bonded directly to the first surface 10a of the base 10. The lid 20 and the base 10 define the accommodation space 23 in which the vibrator element 25 is accommodated. The height L1 of the accommodation space 23 is less than or equal to 0.2×10⁻³ [m], that is, less than or equal to 200 [μm]. Setting the height L1 of the accommodation space 23 to 200 [μm] or less enables a reduction in the height of the vibrator device 1 while ensuring that the vibrator element 25 can be accommodated in the accommodation space 23. The accommodation space 23 contains a vacuum atmosphere, a nitrogen atmosphere, or a helium atmosphere.

Examples of main materials for the first semiconductor substrate 11 of the base 10 and the second semiconductor substrate 21 of the lid 20 include various semiconductor materials, such as silicon, germanium, silicon oxide, gallium nitride, and indium gallium arsenide. Of these, it is preferable that the main materials for the first semiconductor substrate 11 and the second semiconductor substrate 21 be silicon. The reason for this is that silicon is a semiconductor material that is easily available and workable and is inexpensive.

The base 10 and the lid 20 may be bonded directly to each other in any manner that requires no intermediate member between the surfaces to be bonded of two members made of the same material. The bonding method is not limited thereto, and the base 10 and the lid 20 may also be bonded to each other by a technique using glass frit or other material provided therebetween, by a metal eutectic bonding technique in which a metal film formed on the first surface 10a of the base 10 and a metal film formed on the third surface 20a of the lid 20 are bonded together, or by an activation bonding technique in which the first surface 10a of the base 10 and the surface of a metal film, such as a Au film, formed on the third surface 20a of the lid 20 are activated by plasma irradiation and are bonded together.

The vibrator element 25 includes a vibrator substrate 30, a first electrode 31a, and a second electrode 31b. The first electrode 31a is disposed on a side of the vibrator substrate 30 closer to the first semiconductor substrate 11, that is, on the base 10 side. The second electrode 31b is disposed on a side of the vibrator substrate 30 farther from the first semiconductor substrate 11, that is, on the lid 20 side. The first electrode 31a and the second electrode 31b each include an excitation electrode 32, a pad electrode 34, and a lead electrode 33. The excitation electrode 32 vibrates the vibrator substrate 30. The pad electrode 34 outputs a vibration signal to the outside and fixes and the vibrator element 25 to the base 10. The lead electrode 33 forms an electrical connection between the excitation electrode 32 and the pad electrode 34. The second electrode 31b further includes a side electrode 35 which forms an electrical connection between the lead electrode 33 formed over the vibrator substrate 30 and the pad electrode 34 formed under the vibrator substrate 30. The excitation electrode 32 included in the first electrode 31a and the excitation electrode 32 included in the second electrode 31b are equal in area and coincide with each other when viewed in plan view in the Z direction.

The vibrator element 25 is disposed on the first surface 10a side of the base 10, and the pad electrodes 34 of the vibrator element 25 are fixed to the internal terminals 12 of the base 10 with conductive bonding members 41, such as a conductive adhesive or gold bumps, disposed therebetween. Thus, the excitation electrodes 32 of the vibrator element 25 are electrically connected to the oscillation circuit 51 with the conductive bonding members 41 and the internal terminals 12 disposed therebetween and are thus capable of vibrating the vibrator substrate 30. An AT-cut quartz crystal substrate, an SC-cut quartz crystal substrate, a BT-cut quartz crystal substrate, or the like may be used as the vibrator substrate 30.

The base 10 and the lid 20 are the first semiconductor substrate 11 and the second semiconductor substrate 21 connected to the ground potential and having the same conductivity type. As a result, it is possible to block external electromagnetic noise that is superimposed on the first electrode 31a and the second electrode 31b of the vibrator element 25 and can cause malfunctions, such as abnormal oscillation and deterioration of the quality of output signals. Accordingly, a vibrator device 1 that is less susceptible to external electromagnetic noise and has excellent oscillation characteristics can be provided.

However, since the base 10 and the lid 20 are the first semiconductor substrate 11 and the second semiconductor substrate 21 connected to the ground potential and having the same conductivity type, a parasitic capacitance is more likely to occur between the first semiconductor substrate 11 and the first electrode 31a or between the second semiconductor substrate 21 and the second electrode 31b. Accordingly, a capacitance C that occurs between the semiconductor substrates 11 and 21 and the electrodes 31a and 31b was investigated.

The capacitance C of a parallel-plate capacitor is generally given by Equation (1):

$$C = ε \times ( S / d ) \qquad ( 1 )$$

Here, C is the capacitance [F], ε is the permittivity [F/m], S is the area [m²], and d is the distance [m] between conductive plates facing each other.

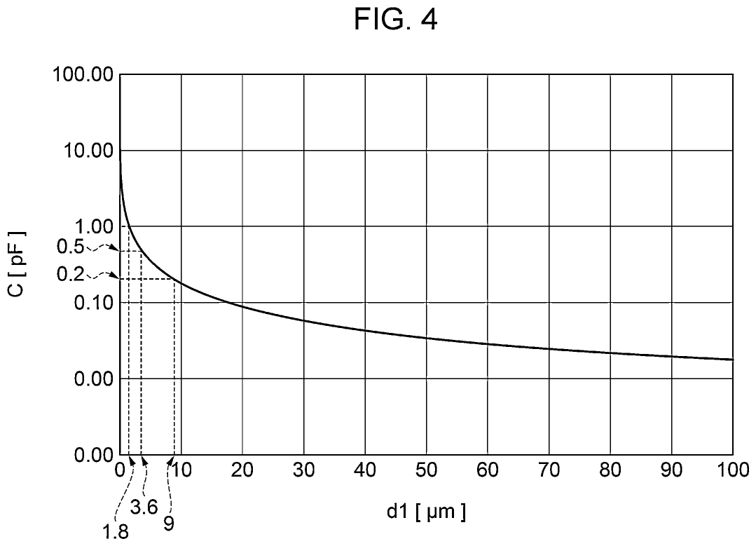

FIG. 4 illustrates the results of simulations on the capacitance C as determined based on Equation (1) with different values of the distance d1 between the first semiconductor substrate 11 and the first electrode 31a.

Simulations were performed with different values of d1 under the following conditions: the accommodation space 23 contained a vacuum atmosphere; the permittivity ε of vacuum was 8.85419×10⁻¹² [F/m]; and the area S1 of the first electrode 31a was 2.0×10⁻¹⁰ [m²]. The area S1 of the first electrode 31a is the sum of the areas of the excitation electrode 32, the lead electrode 33, and the pad electrode 34 that face the first semiconductor substrate 11. In FIG. 4, the results of the simulations on the capacitance C versus the distance d1 are expressed by an approximate curve.

The approximate curve in FIG. 4 indicates that there is a tendency for the capacitance C to decrease exponentially as the distance d1 increases and to converge to about 0.01 [pF] with the distance d1 being greater than or equal to 1.4 [μm].

Referring to FIG. 4, the capacitance C is 1.0 [pF] when the distance d1 is 1.8 [μm]. This means that the capacitance C between the first semiconductor substrate 11 and the first electrode 31a can be reduced to 1.0 [pF] or less when the distance d1 is greater than or equal to 1.8 [μm]. That is, the capacitance C can be reduced to 1.0 [pF] or less when d1≥ε×S1×10¹².

Referring to FIG. 4, the capacitance C is 0.5 [pF] when the distance d1 is 3.6 [μm]. This means that the capacitance C between the first semiconductor substrate 11 and the first electrode 31a can be reduced to 0.5 [pF] or less when the distance d1 is greater than or equal to 3.6 [μm]. That is, the capacitance C can be reduced to 0.5 [pF] or less when d1≥2×ε×S1×10¹².

Referring to FIG. 4, the capacitance C is 0.2 [pF] when the distance d1 is 9.0 [μm]. This means that the capacitance C between the first semiconductor substrate 11 and the first electrode 31a can be reduced to 0.2 [pF] or less when the distance d1 is greater than or equal to 9.0 [μm]. That is, the capacitance C can be reduced to 0.2 [pF] or less when d1≥5×ε×S1×10¹².

Next, as with the relation between the distance d1 and the capacitance C between the first semiconductor substrate 11 and the first electrode 31a, the relation between the distance d2 and the capacitance C between the second semiconductor substrate 21 and the second electrode 31b was investigated by simulations with different values of d2 under the following conditions: the accommodation space 23 contained a vacuum atmosphere; the permittivity ε of vacuum was 8.85419×10⁻¹² [F/m]; and the area S2 of the second electrode 31b was 2.0×10⁻¹⁰ [m²]. The simulations gave the same results as those expressed by the approximate curve in FIG. 4. Thus, the capacitance C between the second semiconductor substrate 21 and the second electrode 31b can be reduced to 1.0 [pF] or less when d2≥ε×S2×10¹².

The capacitance C between the second semiconductor substrate 21 and the second electrode 31b can be reduced to 0.5 [pF] or less when d2≥2×ε×S2×10¹².

The capacitance C between the second semiconductor substrate 21 and the second electrode 31b can be reduced to 0.2 [pF] or less when d2≥5×ε×S2×10¹².

In addition to the simulations in which the accommodation space 23 contained a vacuum atmosphere, simulations in which the accommodation space 23 contained a nitrogen atmosphere and simulations in which the accommodation space 23 contained a helium atmosphere were performed. The permittivity of nitrogen (ε=8.85955×10⁻¹² [F/m]) and the permittivity of helium (ε=8.85484×10⁻¹² [F/m]) are each very close to the permittivity of vacuum (ε=8.85419×10⁻¹² [F/m]); therefore, the approximate curve of the capacitance C was substantially in agreement with the approximate curve in FIG. 4. Thus, even if the accommodation space 23 contains a nitrogen atmosphere or a helium atmosphere, the capacitance C can be reduced to 1.0 [pF] or less when the distance d1 between the first semiconductor substrate 11 and the first electrode 31a is greater than or equal to 1.8 [μm]. Likewise, the capacitance C can be reduced to 0.5 [pF] or less when the distance d1 between the first semiconductor substrate 11 and the first electrode 31a is greater than or equal to 3.6 [μm], and the capacitance C can be reduced to 0.2 [pF] or less when the distance d1 between the first semiconductor substrate 11 and the first electrode 31a is greater than or equal to 9.0 [μm]. The accommodation space 23 may therefore contain any of a vacuum atmosphere, a nitrogen atmosphere, and a helium atmosphere. The accommodation space 23 may contain an inert gas atmosphere other than a nitrogen atmosphere and a helium atmosphere as long as the permittivity of the inert gas atmosphere is substantially equal to the permittivity of vacuum.

The inequality 3.1684×10⁻¹² [m²]≤S1≤4.45556×10⁻⁸ [m²] holds, where S1 is the area of the first electrode 31a. When the electrode area falls within this range, it is possible to reduce the parasitic capacitance to 1.0 [pF] or less while increasing the vibration efficiency to maintain the crystal impedance (CI) value.

In the present embodiment, the first semiconductor substrate 11 and the second semiconductor substrate 21 connected to the ground potential and having the same conductivity type are used as the base 10 and the lid 20. However, the base 10 and the lid 20 are not limited thereto, and a nonconductive substrate made of, for example, glass may be used as the base 10 or the lid 20. When a nonconductive substrate is used as the base 10, the second semiconductor substrate 21 in the present embodiment corresponds to the first semiconductor substrate 11, the second electrode 31b corresponds to the first electrode 31a, and the distance d2 between the second semiconductor substrate 21 and the second electrode 31b corresponds to d1.

As mentioned above, the inequalities L1≤0.2×10⁻³ [m] and d1≥ε×S1×10¹² hold for the vibrator device 1 according to the present embodiment, where L1 is the height of the accommodation space 23, and d1 is the distance between the first semiconductor substrate 11 and the first electrode 31a. Accordingly, a reduction in the height of the vibrator device 1 can be achieved, and the capacitance C between the first semiconductor substrate 11 and the first electrode 31a can be reduced to 1.0 [pF] or less. This enables a reduction in the parasitic capacitance between the first semiconductor substrate 11 and the first electrode 31a and thus inhibits deterioration of electrical characteristics, such as the start-up characteristics of the oscillator and the output characteristics of oscillation signals. Specifically, the deterioration of the electrical characteristics also includes a narrower variable frequency range and unstable oscillation start-up due to insufficient negative resistance of the oscillation circuit 51.

The inequalities L1≤0.2×10⁻³ [m] and d1≥2×ε×S1×10¹² also hold, where L1 is the height of the accommodation space 23, and d1 is the distance between the first semiconductor substrate 11 and the first electrode 31a. Accordingly, a reduction in the height of the vibrator device 1 can be achieved, and the capacitance C between the first semiconductor substrate 11 and the first electrode 31a can be reduced to 0.5 [pF] or less. This enables a further reduction in the parasitic capacitance between the first semiconductor substrate 11 and the first electrode 31a and thus further inhibits deterioration of electrical characteristics, such as the start-up characteristics of the oscillator and the output characteristics of oscillation signals.

The inequalities L1≤0.2×10⁻³ [m] and d1≥5×ε×S1×10¹² also hold, where L1 is the height of the accommodation space 23, and d1 is the distance between the first semiconductor substrate 11 and the first electrode 31a. Accordingly, a reduction in the height of the vibrator device 1 can be achieved, and the capacitance C between the first semiconductor substrate 11 and the first electrode 31a can be reduced to 0.2 [pF] or less. This enables a still further reduction in the parasitic capacitance between the first semiconductor substrate 11 and the first electrode 31a and thus still further inhibits deterioration of electrical characteristics, such as the start-up characteristics of the oscillator and the output characteristics of oscillation signals.

### 2. Second Embodiment

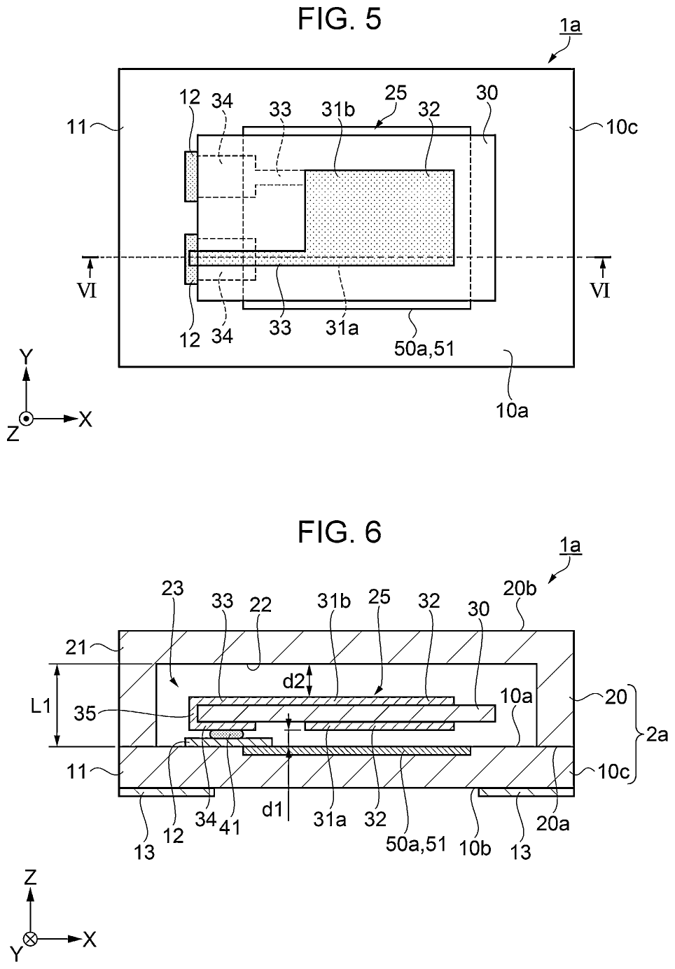

Next, a vibrator device 1a according to a second embodiment is described below with reference to FIGS. 5 and 6.

For convenience of describing the internal configuration of the vibrator device 1a, FIG. 5 illustrates a state in which the lid 20 is removed from the vibrator device 1a.

The vibrator device 1a according to the present embodiment is identical to the vibrator device 1 according to the first embodiment except for the position of a circuit portion 50a of a base 10c. The following description is given with a focus on the difference between the present embodiment and the first embodiment described above, and like elements are denoted by the same reference signs and will not be described here.

As illustrated in FIGS. 5 and 6, the vibrator device 1a includes the vibrator element 25, the base 10c, and the lid 20. The base 10c and the lid 20 constitute a package 2a in which the vibrator element 25 is accommodated.

The base 10c includes the circuit portion 50a, which is located on a side of the first semiconductor substrate 11 closer to the vibrator element 25, that is, on the first surface 10a side. The circuit portion 50a includes the oscillation circuit 51 electrically connected to the vibrator element 25.

This configuration can produce effects similar to those produced in the first embodiment when the height L1 of the accommodation space 23 and the distance d1 between the first semiconductor substrate 11 and the first electrode 31a are equal to or less than the respective predetermined values.

### 3. Third Embodiment

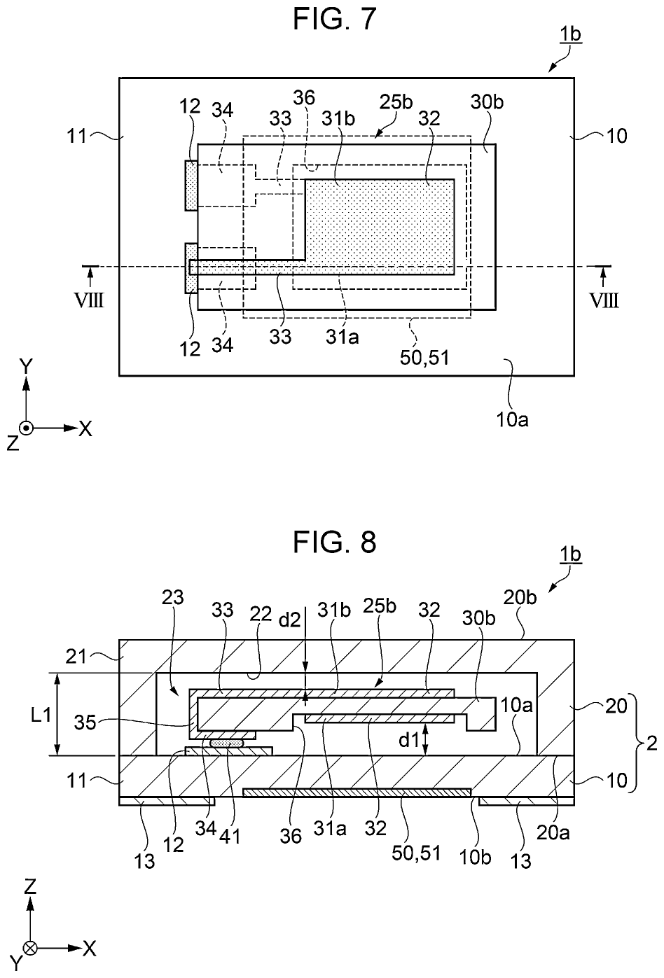

Next, a vibrator device 1b according to a third embodiment is described below with reference to FIGS. 7 and 8.

For convenience of describing the internal configuration of the vibrator device 1b, FIG. 7 illustrates a state in which the lid 20 is removed from the vibrator device 1b.

The vibrator device 1b according to the present embodiment is identical to the vibrator device 1 according to the first embodiment except for the structure of a vibrator element 25b. The following description is given with a focus on the difference between the present embodiment and the first embodiment described above, and like elements are denoted by the same reference signs and will not be described here.

As illustrated in FIGS. 7 and 8, the vibrator device 1b includes the vibrator element 25b, the base 10, and the lid 20. The base 10 and the lid 20 constitute the package 2 in which the vibrator element 25b is accommodated.

The vibrator element 25b has a recess 36 that is open on the base 10 side in the center of the vibrator substrate 30b. The excitation electrode 32 included in the first electrode 31a is disposed on an inner bottom surface of the recess 36. The distance d2 between the second semiconductor substrate 21 and the second electrode 31b is therefore less than the distance d1 between the first semiconductor substrate 11 and the first electrode 31a, and the parasitic capacitance is dependent on the distance d2.

This configuration can produce effects similar to those produced in the first embodiment when the height L1 of the accommodation space 23 and the distance d2 between the second semiconductor substrate 21 and the second electrode 31b are equal to or less than the respective predetermined values.

What is claimed is:

1. A vibrator device comprising:
a vibrator element;
a base to which the vibrator element is coupled; and
a lid bonded to the base, the vibrator element being accommodated in an accommodation space between the lid and the base, wherein
at least one of the base or the lid includes a first semiconductor substrate connected to a ground potential and having a conductivity type that is p-type or n-type,
the vibrator element includes a vibrator substrate, a first electrode disposed on a side of the vibrator substrate closer to the first semiconductor substrate, and a second electrode disposed on a side of the vibrator substrate farther from the first semiconductor substrate, and L1≤0.2×10⁻³ and d1≥ε×S1×10¹², wherein
L1 [m] is a height of the accommodation space,
d1 [m] is a distance between the first semiconductor substrate and the first electrode,
S1 [m²] is an area of the first electrode, and
ε [F/m] is a permittivity of the accommodation space.

2. The vibrator device according to claim 1, wherein d1≥2×ε×S1×10¹².

3. The vibrator device according to claim 1, wherein d1≥5×ε×S1×10¹².

4. The vibrator device according to claim 1, wherein
the first electrode is disposed on a side of the vibrator substrate closer to the base,
the second electrode is disposed on a side of the vibrator substrate closer to the lid,
the base includes the first semiconductor substrate,
the lid includes a second semiconductor substrate connected to the ground potential and having the conductivity type,
d1≥ε×S1×10¹², and
d2≥ε×S2×10¹², wherein
d2 [m] is a distance between the second semiconductor substrate and the second electrode, and
S2 [m²] is an area of the second electrode.

5. The vibrator device according to claim 4, wherein
d1≥2×ε×S1×10¹², and
d2≥2×ε×S2×10¹².

6. The vibrator device according to claim 4, wherein
d1≥5×ε×S1×10¹², and
d2≥5×ε×S2×10¹².

7. The vibrator device according to claim 4, wherein
the base includes a circuit portion located on a side of the first semiconductor substrate farther from the vibrator element, and
the circuit portion includes an oscillation circuit electrically connected to the vibrator element.

8. The vibrator device according to claim 4, wherein
the base includes a circuit portion located on a side of the first semiconductor substrate closer to the vibrator element, and
the circuit portion includes an oscillation circuit electrically connected to the vibrator element.

9. The vibrator device according to claim 1, wherein 3.1684×10⁻¹²≤S1≤4.45556×10⁻⁸.

10. The vibrator device according to claim 1, wherein the accommodation space contains a vacuum atmosphere, a nitrogen atmosphere, or a helium atmosphere.

11. The vibrator device according to claim 1, wherein
3.1684×10⁻¹²≤S1≤4.45556×10⁻⁸, and
the accommodation space contains a vacuum atmosphere, a nitrogen atmosphere, or a helium atmosphere.
